(19) United States
(12) Patent Application Publication
(10) Pub. No.: US 2026/0251683 A1
(43) Pub. Date: Aug. 27, 2026

(54) Monitoring device for wide-dynamic-range currents, in particular for monitoring traction currents

(71) Applicant: Knick Elektronische Messgeräte GmbH & Co. KG, Berlin (DE)

(72) Inventors: Lars SCHWEIZER, Berlin (DE); Rayk HÖFEMANN, Langelsheim (DE); Torsten HAHN, Berlin (DE)

(73) Assignee: Knick Elektronische Messgeräte GmbH & Co. KG, Berlin (DE)

(21) Appl. No.: 18/855,394

(22) PCT Filed: Mar. 20, 2023
(86) PCT No.: PCT/EP2023/057071

§ 371 Date: Oct. 9, 2024

(30) Foreign Application Priority Data
Apr. 12, 2022 (DE) 10 2022 203 697.2

(51) Int. Cl. G01R 15/14

(52) U.S. Cl. CPC G01R 15/146

(57) ABSTRACT

A monitoring apparatus for wide-dynamic-range currents includes a shunt resistor in a supply line carrying the current to be monitored. A measurement amplifier circuit has an input side which receives the voltage drop across the shunt resistor, with an overall dynamic range that covers normal-operation currents and fault currents. An evaluation device receives the output signal of the measurement amplifier circuit. A single-channel measurement amplifier circuit includes a measurement amplifier that reproduces the overall dynamic range of the input voltage and a compression stage, which receives the output signal of the measurement amplifier. At least two different transfer functions include a first transfer function which converts the measurement range of the normal-operation currents at high resolution and a second transfer function which compresses the dynamic range of the input voltage, converts the measurement range of the fault currents at lower resolution into an output signal of the measurement amplifier circuit.

### CROSS-REFERENCE TO RELATED APPLICATION

This application is a national stage application, filed under 35 U.S.C. § 371, of International Patent Application PCT/EP2023/057071, filed on Mar. 20, 2023, which claims the benefit of German Patent Application DE 10 2022 203 697.2, filed on Apr. 12, 2022. The content of German patent application DE 10 2022 203 697.2 is incorporated herein by way of reference.

### TECHNICAL FIELD

The disclosure relates to a monitoring apparatus for wide-dynamic-range currents, in particular for monitoring traction currents, drive currents of installations or the like.

### BACKGROUND

The present disclosure is concerned with particularly robust equipment for measuring power-engineering currents, which can change over a very wide range even within short periods of time. This relates, by way of example, to electric-motor drives for industrial facilities, where electric motors and the masses to be accelerated lead to high starting currents or in which blockages in the drivetrain lead to high torques, or ultimately very high motor currents. An example that may be cited for such industrial facilities is large mills or roll drives in steel production. Particularly in the field of supplying power to electric railways, however, the current amplitudes are particularly dynamic. It is therefore particularly important in the so-called traction power substations set up specifically for this purpose to ensure a reliable and safe supply of current to the railway lines.

Often, electrified railway lines in cities run both underground and aboveground. The electric rail vehicles are usually supplied with the necessary drive power by way of overhead cables or by way of so-called power rails. The return current from the rail vehicle is provided by way of the metal tracks.

It is customary in local public transport to supply rather low voltages of, for example, nominally 750 V or nominally 1500 V DC to the overhead cables, or to the power rail. These rather low voltages can therefore result in currents of up to nominally 4000 A or more during normal operation, depending on the drive power required. So-called substations are therefore necessary at regular intervals along the railway line so that power can be repeatedly supplied in each case. These substations are generally at intervals of a few kilometres from one another in order to repeatedly compensate for resistive losses in the overhead cables, power rails and tracks.

Sometimes, multiple rail vehicles are also travelling on the same line section, and these may each be in different but also identical traction situations, such as acceleration, motion, or braking or stopped. It is therefore understandable that the current in the supply cable has a highly time-dependent characteristic and a certain vehicle-location-dependent characteristic, which can change within fractions of seconds.

Additionally, electrified railway lines are subject to a higher risk of short circuits compared to other power lines, for example as a result of animal damage, tree damage, damage to rail vehicles, the effect of lightning, etc. Such a fault leads to sometimes very sharp current rises, which can be a multiple of the normal traction current, depending on the distance of the short circuit from the substation. FIG. 7 shows the known, possible time characteristic of the current in the event of a short circuit in which a current of up to 19,000 A can be reached within approximately 7 milliseconds. This peak value is more than four times the regular traction current.

For many decades, shunt resistors for the kiloamp range have been established as particularly robust current sensors that are also reliable, resistant to short circuits and accurate in the long term. A European standard defines fault currents on the basis of faults of up to 125 kiloamps. To allow short circuits to be reliably distinguished from regular current characteristics, apparatuses called protection relays, or protective devices, are used that, in particular, analyse the temporal current characteristic and, if a short circuit is detected, cause an electrical power interrupter, or circuit breaker, to interrupt the circuit. This must take place within a few milliseconds before the current has risen to excessively high values and has these high values for too long a time and damage occurs in the substation and the electrical power interrupter and ultimately also the supply cables. Consideration should also be given to the fire risk that arises as a result of the effect of heat and arc phenomena at the location of the short circuit, which is a particular problem in underground railway stations and tunnels. As the shunt resistors used are at a high potential with reference to earth, DC-isolating measurement amplifiers are used. These measurement amplifiers undertake amplification of the voltages dropped across the shunt resistors, which are only a few millivolts, and output the amplified signals at their output again as a current or voltage signal in DC-isolated fashion. As a result of an internal isolating signal and power transmission system, they therefore have the ability to keep dangerously high voltages that are present across the shunt resistor away from the measurement signal output and also from the power supply terminal. Consequently, they therefore prevent not only possible personal injury as a result of excessively high body currents but thus also measurement errors as a result of undesirable fault currents and also damage to the protective device, for example.

Unwanted stoppage of a rail vehicle is a risk that has to be taken seriously, in particular on line sections outside railway stations; in particular in tunnels or on underground railway lines, e.g. safe evacuation of individuals is particularly difficult.

The increasing demands on reliability in particular for the supply of traction current mean that the condition, or wear, of the electric power interrupters, or circuit breakers, must also be monitored. In this regard, EP 2 328 159 A1 describes the possibility of using measured current values to make statements about the wear of circuit breakers in order to be able to carry out accurate maintenance of such electric power interrupters.

### SUMMARY

FIG. 8 shows a typical monitoring apparatus of the type in question, as can be found for example in a DC substation for supplying power to a railway line, and a shunt resistor 103 in the supply cable 104 carrying the current I_{drive} to be monitored, a measurement amplifier circuit 117, the input side of which receives the voltage drop Uᵢₙ across the shunt resistor 103, with an overall dynamic range that covers normal-operation currents and fault currents, and a protective device 111 that receives the output signal (I_{M1}, I_{M2}) of the measurement amplifier circuit 117, to record normal-operation and fault currents.

Specifically, a DC substation is supplied with power e.g. from the polyphase AC medium-voltage grid, or AC high-voltage grid, via a transformer that sufficiently reduces the voltage. This reduced polyphase AC voltage is supplied by way of the supply cable 100 to an electronic and if necessary controlled power rectifier 101, which then has one or more DC outputs 102 having e.g. an output voltage of nominally +1500 V DC. This output 102 can use the power shunt resistor 103 to deliver the necessary current I_{drive} to the circuit breaker, or electric current interrupter, 105 via the cable 104. The shunt resistor 103 may also be arranged downstream of the electric power interrupter 105.

In normal traction situations, the current I_{drive} can assume values of up to several thousand amps, for example 2000 A. The power that is therefore provided would thus be nominally 3 MW in this case. In the closed condition, the electric power interrupter 105 then routes this power to the overhead cable, or power rail, via the cable 106. The return current from the rail vehicle flows via the traction rails to the often earthed point 107, which is also connected to the power rectifier 101 (0 volt terminal of 101).

The circuit breaker 105 is electrically controlled by the so-called protective device 111 (protection relay) by way of the control cables 115 connected to the Control terminal. These control cables 115 also report the particular prevailing switch position back to the protective device 111 via the Control terminal. It should also be mentioned that the circuit breaker 105 normally also has its own electromagnetic tripping means that automatically open the circuit breaker in the event of very high overcurrents, that is to say interrupt the circuit without an open command from the protective device 111. This affords additional safety in the event of a fault in the protective device.

The protective device 111 has the measurement inputs I_{M1}, I_{M2} and UM for the measured variables of the traction current I_{drive} (split into 2 measurement channels I_{M1} and I_{M2}) and the traction voltage at the supply point, which is tapped off from the cable 104 via a voltage measurement transducer (not shown) and supplied to the measurement input UM. The protective device also has a communication terminal COM that can use a communication protocol customary in substations to report events, conditions, measured values, etc., to a control centre via a data cable 110, e.g. a type of Ethernet cable, and that can also be used to configure the protective device from a control centre if necessary. Additionally, both the measurement amplifiers 109 and 110 and the protective device 111 each have a terminal 108 for supplying auxiliary power, for example 24 V DC or 110 V DC.

The shunt voltage Uᵢₙ is routed to the inputs of the DC-isolating measurement amplifiers 109 and 110 via suitable cables 118. The first measurement amplifier 109 maps the shunt voltage Uᵢₙ to an output current Iₒᵤₜ₁ and delivers this current to the measurement input I_{M1}. The second measurement amplifier 110 maps the shunt voltage Uᵢₙ to an output current Iₒᵤₜ₂ and delivers this current to the measurement input I_{M2}. Normal maximum values of such signal currents may be e.g. 20 mA (standard signal in automation engineering). The shunt voltage Uᵢₙ is proportional to I_{drive}, normal values being for example 60 mV for a current of 4000 A, which corresponds to a shunt resistance of 15 μohm.

In order to define the properties of the measurement amplifier 109, a linear transfer function Iₒᵤₜ₁=tf₁(Uᵢₙ) can be specified:

$${tf}_{1} ( {U}_{i n} ) = {a}_{0} + {a}_{1} * {U}_{i n} = {I}_{out 1}$$

where a₁=dIₒᵤₜ₁/dUᵢₙ, meaning that the coefficient a₁ is synonymous with the gradient of the transfer function tf₁.

In order to define the properties of the measurement amplifier 110, a linear transfer function Iₒᵤₜ₂=tf₂(Uᵢₙ) can be specified:

$${tf}_{2} ( {U}_{i n} ) = {b}_{0} + {b}_{1} * {U}_{i n} = {I}_{out 2}$$

where b₁=dIₒᵤₜ₂/dUᵢₙ, meaning that the coefficient b₁ is synonymous with the gradient of this transfer function.

A normal interpretation for the two transfer functions is a₁=k*b₁, where k=10 (example).

The coefficients a₀ and b₀ of the transfer functions tf₁ and tf₂ determine the output value of the measurement amplifiers 109 and 110 for the input voltage Uᵢₙ=0. In the case of measurement amplifiers with a so-called live-zero current output (e.g. 4 . . . 20 mA), these coefficients are thus then greater than zero; in the case of a dead-zero output (e.g. 0 . . . 20 mA) they are equal to zero. The outputs of the measurement amplifiers 109 and 110 may also be in the form of voltage outputs.

The use of two measurement channels permits for example the measurement channel I_{M1} to be used to reproduce the regular traction current (e.g. 4000 A max) and the measurement channel I_{M2} to be used to reproduce k times the traction current (e.g. 40 000 A max). A requirement in this case is for each of the measurement channels (measurement inputs) of the protective device 111 to process the same range of the signal currents output by the measurement amplifiers at the inputs I_{M1} and I_{M2}. Similarly, the maximum current that is able to be output by each of the measurement amplifiers 109 and 110 is limited to the same value. This means that an overcurrent event, that is to say with values I_{drive} e.g. upward of greater than 4000 A, results in the measurement amplifier 109 delivering a constant maximum value, or the measurement input I_{M1} being overdriven, that is to say in any case no further statement about the actual level of the current I_{drive} being possible with this measurement channel. It is precisely for this case that the measurement channel I_{M2}, which can still linearly reproduce values greater than 4000 amps, comes into play. The protective device 111 then has the task of suitably evaluating the information from both measurement channels in order to record normal-operation and fault currents and if necessary to derive appropriate actions therefrom, such as tripping the electric power interrupter 105.

This split into two measurement channels, which is known from the prior art, affords the opportunity to reproduce both the traction current and the short-circuit current, or fault current, at good resolution and with low noise. The protective device 111 normally uses digital signal processing. After the electrical signals of the measurement channels I_{M1}, I_{M2} and UM (terminal 114) have been digitized in the protective device 111 with limited temporal and amplitude-based resolution, algorithms assess the measurement channel information and the time characteristics thereof in order to control the electric power interrupter 105 according to the situation. Even with very large values for I_{drive}, the second measurement channel I_{M2} still permits statements about the level of the short-circuit current, which is important for determining a maintenance requirement for the contacts, or the circuit breaker as a whole (e.g. arc-extinguishing chamber, electrical/mechanical actuating drive, etc.). Naturally, the respective transfer function of the measurement amplifiers 109, 110 and the association with the measurement channel must be “known” to the protective device 111. It should finally be mentioned that, instead of two single-channel measurement amplifiers, one two-channel measurement amplifier 117 can also be used. Such a two-channel device is implemented by the dashed box in FIG. 8, that is to say in a common housing.

In the case of the described monitoring apparatus according to the prior art, the two-channel design means that a high level of equipment complexity is discernible. This is disadvantageous with regard to the reliability and economic viability of known monitoring apparatuses. Accordingly, the disclosure is based on the object of providing a monitoring apparatus of the type in question that is of structurally simpler design in order to avoid the aforementioned disadvantages, without relevant losses of measurement quality.

This object is achieved by way of the single-channel measurement amplifier circuit specified in the characterizing part of Claim 1, which is provided with a measurement amplifier that reproduces the overall dynamic range of the input voltage and with a compression stage, which receives the output signal of the measurement amplifier, having at least two different transfer functions, a first transfer function of which converts the measurement range of the normal-operation currents at high resolution and the second transfer function of which, which compresses the dynamic range of the input voltage, converts the measurement range of the fault currents at lower resolution into an output signal of the measurement amplifier circuit.

The evaluation device can quite generally be implemented for example by way of conventional programmable logic controllers or other measurement and control devices. Such evaluation devices generally have terminals for data communication and if necessary also outputs for controlling actuators, relays, converters, etc. A characteristic of all evaluation devices is that they have measurement inputs that can process only a limited dynamic range. It is thus not pivotal for the application of the monitoring apparatus whether a circuit breaker, or electric power interrupter, is ultimately controlled. For many industrial or infrastructure facilities, it is generally very useful and, as a result of the low complexity, also appealing to significantly extend the current dynamic range recorded by way of the measurement inputs of the evaluation devices. This permits e.g. extended diagnosis functions. In the case of drivetrains, blockages can result for example in the extended dynamic range permitting a statement about the possible damage to couplings, shafts, rollers, bearings or other mechanical, electrical or electromechanical components.

It can be seen that the monitoring apparatus now requires only one preferably DC-isolating measurement amplifier for the shunt voltage Uᵢₙ. Accordingly, the evaluation device now also requires only one measurement channel I_{M} for the current. Nevertheless, this greatly reduced and therefore much cheaper arrangement allows both normal-operation currents, such as the regular operating current of an industrial installation or the traction current of a railway vehicle, and fault currents, such as a short-circuit current, to be recorded by the protective device with sufficient accuracy. It is thus quite generally possible to monitor wide-dynamic-range motor currents of electric drive motors of any type, such as in industrial facilities or vehicles. The evaluation device need have only one current measurement channel.

The text below describes in particular the wide-dynamic-range monitoring of currents in the supply of power to electric railways as an illustrative application. Use of the monitoring apparatus is expressly not limited thereto, however. The text below therefore also uses the term evaluation device as a generic term that also covers a protective device (protection relay), as is specified as a preferred embodiment and used for example in the railway power supply in substations for supplying power to railway lines.

The other dependent claims specify preferred developments of the invention. As such, although the transfer functions may be suitable nonlinear functions, it is least complex in terms of evaluation if the transfer functions are linear functions having different gradients.

With regard to the orders of magnitude that arise for normal-operation and fault currents in practice, it is advantageous if the first, high-resolution transfer function has a gradient that corresponds to a multiple of, preferably to at least 5 times, particularly preferably to approximately 10 times, the gradient of the second, low-resolution transfer function.

According to another advantageous embodiment, the high-resolution transfer function may be designed so as to be shifted at the origin. This is necessary for a measurement amplifier that has a so-called live-zero current output. This measure thus increases the spectrum of use of the monitoring apparatus.

If required for measurement purposes, the apparatus's division of the transfer functions does not have to remain limited to one particular transfer function per resolution range. According to one development, there may be provision for each of the transfer functions to be made up of two or more different sub-transfer functions. This increases the variability of the amplification characteristic of the measurement amplifier circuit.

The transfer functions may further be designed to form positive and negative currents. This allows even negative input voltages to be processed and to have their dynamic range compressed. This affords the opportunity to measure even negative currents, as arise for example in the form of negative traction currents as a result of recuperation during braking processes of rail vehicles that feed back to the grid. These transfer functions then also permit use in the AC current domain, for example for AC traction power supplies.

According to another advantageous embodiment, the measurement amplifier circuit is designed to have DC isolation between the input and the output in a manner known per se. This ensures that dangerously high voltages across the shunt resistor and thus at the measurement input are kept away from the measurement signal output and the power supply terminal. This benefits the product safety of the monitoring apparatus.

The same aim is served by the optional DC-isolating auxiliary power supply for supplying power to the measurement amplifier circuit.

Finally, the monitoring apparatus can incorporate cable break monitoring for the cable connection between the shunt resistor and the measurement amplifier circuit by virtue of the measurement amplifier impressing a low test current into this cable connection and the shunt resistor. A cable break then takes the measurement amplifier to its drive limit, which is unambiguously detectable as a fault condition. The monitoring apparatus is thus optimized further in terms of safety.

### BRIEF DESCRIPTION OF THE DRAWINGS

Further features, details and advantages of the invention will emerge from the description of an exemplary embodiment that follows with reference to the accompanying drawings, in which:

FIG. 1 shows a block diagram of a railway traction power supply with a monitoring apparatus,

FIG. 2 shows a more detailed block diagram of a measurement amplifier circuit used in the monitoring apparatus,

FIG. 3 shows a more detailed block diagram of the supply of power to the measurement amplifier circuit,

FIGS. 4 and 5 show two different current/voltage graphs for the compression characteristic of a compression stage used in the monitoring apparatus,

FIG. 6 shows a circuit diagram of an implementation option for a compression stage with two transfer functions,

FIG. 7 shows a time/current graph for a short-circuit current in a fault condition, and

FIG. 8 shows a block diagram of a railway traction power supply with a monitoring apparatus according to the prior art.

### DETAILED DESCRIPTION

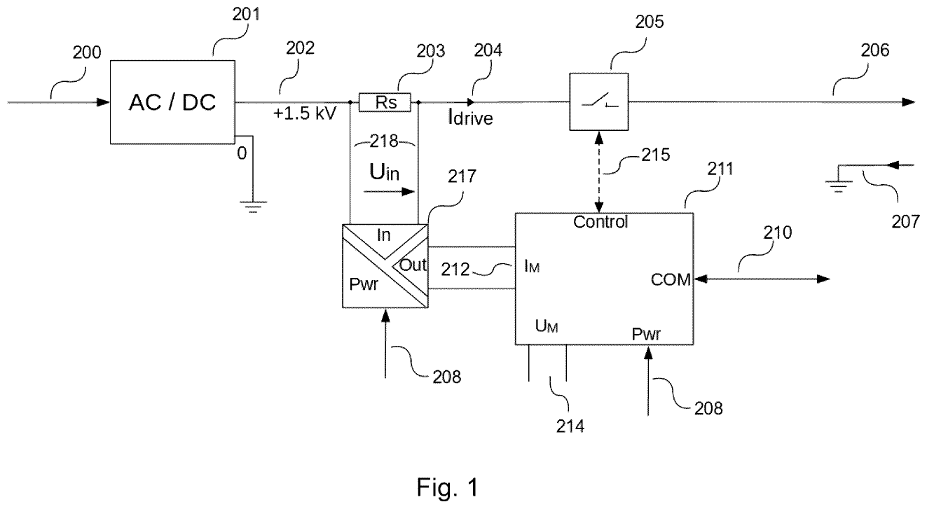

As can be seen from FIG. 1, analogously to the description of the prior art in the introductory part above, the supply of power to a railway line is represented by a supply cable 200, a controlled power rectifier 201 and a shunt resistor 203 in the supply cable 204 carrying the current to be monitored I_{drive}. A measurement amplifier circuit 217, the input side of which receives the voltage drop Uᵢₙ across the shunt resistor 203, with an overall dynamic range that in turn covers normal-operation currents and fault currents is provided. A protective device 211 that receives the output signal (I_{M}) of the measurement amplifier circuit 217 is used to record these normal-operation and fault currents.

Analogously to the prior art, the power rectifier 201 can have one or more DC outputs 202 having e.g. an output voltage of nominally +1500 V DC. This output 202 can use the power shunt resistor 203 to deliver the necessary current I_{drive} to the circuit breaker, or electric power interrupter 205, via the cable 204. The shunt resistor 203 may also be arranged downstream of the electric power interrupter 205.

The electric power interrupter 205 is electrically controlled by the so-called protective device 211 (protection relay) by way of the control cables 215 connected to the Control terminal. These control cables 215 also report the particular prevailing switch position back to the protective device 211 via the Control terminal. The electric power interrupter 205 has its own electromagnetic tripping means that automatically open the circuit breaker in the event of very high overcurrents, that is to say interrupt the circuit without an open command from the protective device 211. This affords additional safety in the event of a fault in the protective device.

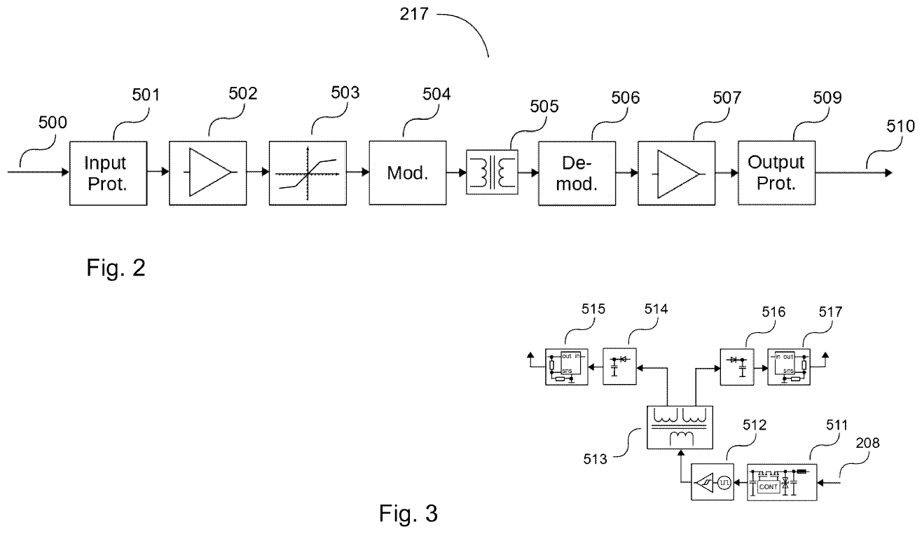

In contrast to the prior art, the measurement amplifier circuit 217 now requires—as can be seen from FIGS. 1 and 2—only one DC-isolating measurement amplifier for the shunt voltage Uᵢₙ and accordingly the protective device 211 also now requires only one measurement channel I_{M} for the current. Nevertheless, this greatly reduced and therefore much cheaper arrangement allows both the traction current and a short-circuit current to be recorded by the protective device 211 with sufficient accuracy, as will become clear from the description below.

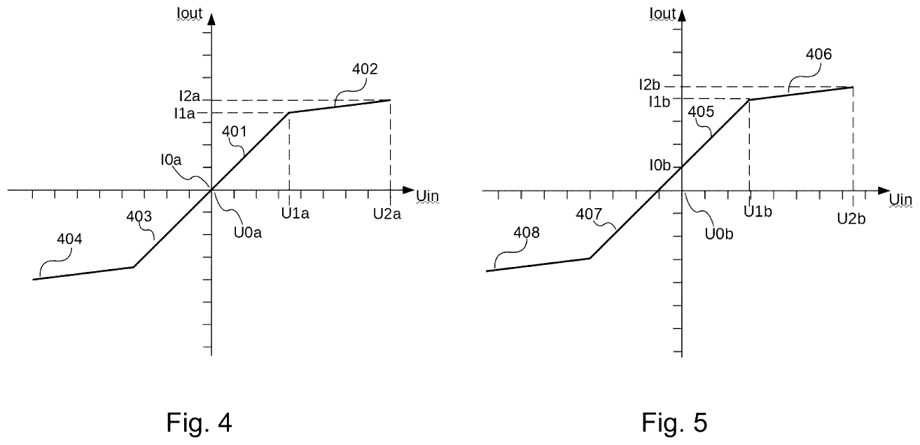

The measurement signal 500 (FIG. 2) is taken to an input protection network 501, which can also have means for implementing cable break monitoring for the cables 218 to the shunt resistor 203, then to a measurement amplifier 502, which can reproduce the entire measurement dynamic range of the input signal linearly, but in amplified fashion, then to a compression stage 503, which operates with a four-part transfer function as shown in FIG. 4, for example, and finally to a modulator 504, which modulates the compressed output signal of the measurement amplifier 502 such that it can be transmitted across a potential barrier 505 (for example a transformer). The output signal of the potential barrier is supplied to a demodulator 506, which recovers the original, compressed signal again. Said signal is passed to an output amplifier 507, which is in the form of a current output, for example.

From there, the output protection network 509 is used to feed the output 510. Instead of the potential barrier 505 in the form of a transformer, other potential barriers such as optocouplers, capacitive couplers, inductive couplers, magnetoresistive couplers or piezoelectric couplers in any form can also be used.

The output amplifier 507 may also be designed as a voltage output or as a current output with different value ranges from those specified above.

The supply of power to the measurement amplifier circuit 217 is provided by way of an auxiliary power supply 208 shown in FIG. 1 and can be explained in more detail with reference to FIG. 3. The voltage (e.g. a DC voltage) supplied by way of the auxiliary power supply 208 is presented to the transformer 513 integrated in the measurement amplifier circuit 217 via a protection network 511 and a, if necessary controlled, chopper 512. The DC-isolated output voltages of said transformer are obtained via the two output windings of the transformer 513 and respective rectifiers 514, 516 and also voltage regulators 515 and 517 for the input section and the output section of the measurement amplifier circuit 217.

The transfer characteristic of the compression stage 503, which provides a function that compresses the dynamic range of the input voltage in the measurement amplifier circuit 217, will now be explained with reference to FIG. 4. This transfer characteristic exhibits the shape of a kinked transfer characteristic curve made up of sections of linear transfer functions having different gradients.

Thus, as shown in FIG. 4, the transfer characteristic curve for positive input voltages can be split into two sections. The respective transfer function associated with the section is valid only for the respective curve section. These transfer functions are thus individually in force only when the voltage Uᵢₙ is in the respective specified range.

### A First Section 401 has a Transfer Function

$${tf}_{401} ( {U}_{i n} ) = {c}_{0} + {c}_{1} * {U}_{i n}$$

$$where {c}_{0} = 0 and {c}_{1} = ( {I}_{1 a} - {I}_{0 a} ) / ( {U}_{1 a} - {U}_{0 a} ) .$$

$${tf}_{401} comes into force when {U}_{0 a} \leq {U}_{i n} \leq {U}_{1 a} .$$

### A Second Section 402 has a Transfer Function

$${tf}_{402} ( {U}_{i n} ) = {d}_{0} + {d}_{1} * ( {U}_{i n} - {U}_{1 a} )$$

$$where {d}_{0} = {I}_{1 a} and {d}_{1} = ( {I}_{2 a} - {I}_{1 a} ) / ( {U}_{2 a} - {U}_{1 a} ) .$$

$${tf}_{402} comes into force when {U}_{1 a} < {U}_{i n} .$$

It is clearly discernible in the graph shown in FIG. 4 that c₁ is much greater than d₁, specifically by approximately the factor k=10.

It goes without saying that in the case of a purely analogue electronic implementation the compression stage 503 with its transfer functions such as 401 and 402 may be afflicted with certain fuzzinesses; with this in mind, the “kinks” may be in more or less acute form.

It also goes without saying that further transfer functions tf₄₀₃ and tf₄₀₄ can then take effect for processing negative voltages Uᵢₙ.

In particular the compression stage 503 with the transfer functions described results in it being possible to process the same dynamic range for Uᵢₙ for which the two conventional measurement amplifiers 109 and 110 (or one two-channel measurement amplifier 117) and two measurement channels were previously required in the protective device 111. Although the dynamic compression of the measurement amplifier circuit 217 somewhat decreases the attainable resolution, in particular for the short-circuit current range, this is not significant for detecting wear on the electric power interrupter 205. What is important is that the high resolution remains high enough for the regular traction current. It should be mentioned in this case that the maximum output current range of the measurement amplifier circuit 217 can also go beyond the normal 20 mA. Equivalent circumstances apply to voltage outputs that are possibly used instead of the current outputs.

The graph in FIG. 5 shows a transfer function comprising the sections 405 and 406 that is shifted at the origin. This is necessary e.g. when the measurement amplifier circuit 217 has a so-called live-zero current output. For positive input voltages Uᵢₙ, even an input voltage of 0 mV at the current output is then guaranteed to result in a current of e.g. 4 mA being delivered to the input 212 of the measurement channel I_{M}. Here, the coefficient c₀ is thus greater than zero.

In the graphs relating to the transfer function shown in FIGS. 4 and 5, it can be seen from the sections 403, 404, 407, 408 that even negative input voltages can be processed and also have their dynamics compressed. Therefore even negative currents can be measured. Negative traction currents can arise as a result of recuperation, for example, that is to say during braking processes in rail vehicles that feed back to the grid. Additionally, these transfer functions effective for negative input voltages also permit AC current recordings, e.g. for AC railways or AC drives.

It should be clarified that the dynamic-range-compressing function of the measurement amplifier circuit 217 is not only possible with compression stages 503 having characteristic curves as shown in FIGS. 4 and 5 but is also implementable with other transfer functions comprising even more individual sections. It is also not absolutely necessary to use linear functions. As such, curves or combinations of linear sections comprising curves may also be suitable. What is important is that the protective device 211 can obtain values on its measurement channel 212 that are biuniquely attributable to a specific input voltage and therefore uniquely attributable to a specific current. The measurement amplifier circuit 217 must therefore deliver no ambiguous measurement signals. The sectional transfer functions (or moving transfer functions in the form of curves) must naturally be “known” to the protective device 211 in every case.

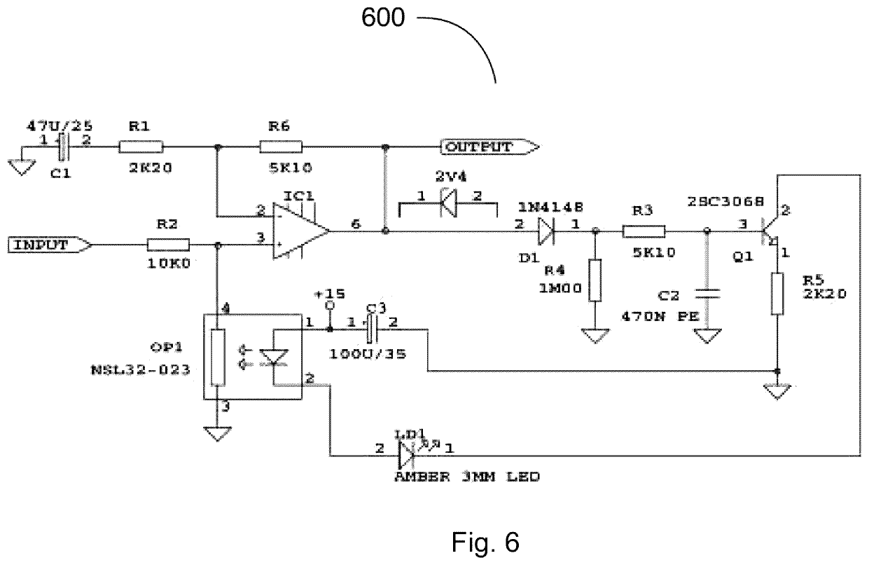

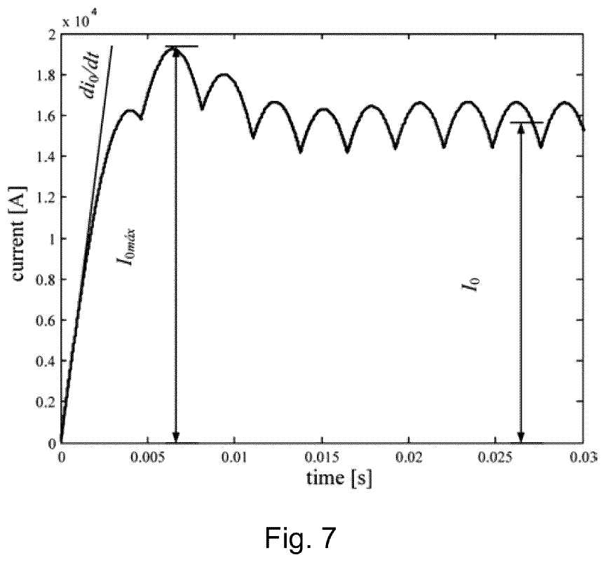

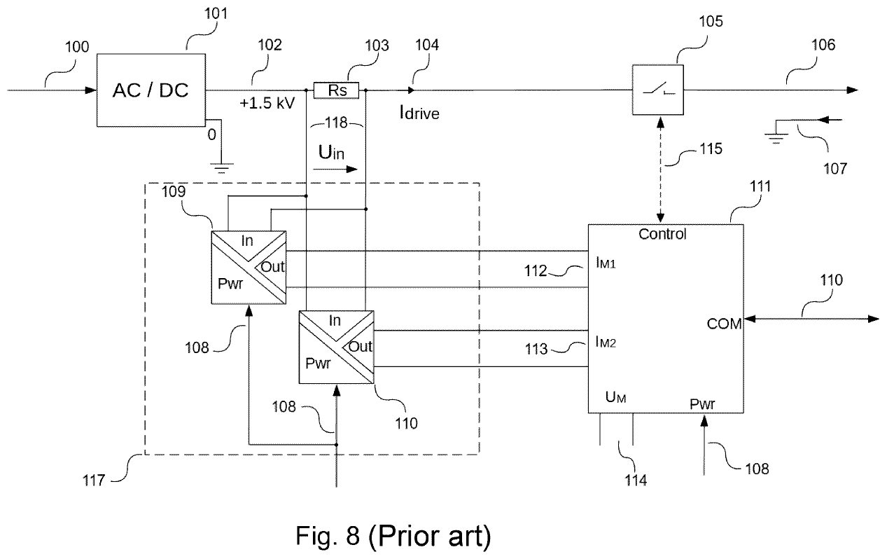

Possible electronic circuits for implementing the compression stage 503 are known in principle in the literature. A possible basic principle is specified for example in a circuit proposal 600 as shown in FIG. 6 from an application report “Compressor Applications for Resistive Optocouplers” from the company Silonex. Additionally, there are similar circuits that use field-effect transistors instead of the specific optocoupler used here.

Although it is also possible to implement the compression stage 503 using digital signal processing, this is not preferred, as it would require complex digitization of the voltage Uᵢₙ in the measurement amplifier itself, which is undesirable.

In principle, it would finally also be possible to arrange the compression stage 503 at any point in the signal path, for example downstream of the demodulator 506, which would not be optimum due to the limited dynamic range of the modulator/demodulator, however. A positioning upstream of the first measurement amplifier 502 would also not be a sensible alternative owing to the tolerances of the characteristic curves.

It is also possible to dispense with the DC isolation between the output-side electronics (506, 507, 509, 510) and the auxiliary power (208, 511, 512). The transformer 513 then contains one winding fewer, and the blocks 516 and 517 can also be omitted. The DC isolation of the input-side electronics (500, 501, 502, 503, 504, 514, 515) from the output-side electronics (506, 507, 509, 510, possibly 517) and the auxiliary power supply (208, 511, 512) is maintained.

1.-10. (canceled)

11. A monitoring apparatus for wide-dynamic-range currents, comprising:
a supply line (204) carrying a current (I_{drive}) to be monitored;
a shunt resistor (203) in the supply line (204);
a measurement amplifier circuit (217),
wherein an input side of the measurement amplifier circuit (217) receives a voltage drop (Uᵢₙ) across the shunt resistor (203), and
wherein an overall dynamic range of the measurement amplifier circuit (217) covers normal-operation currents and fault currents; and
an evaluation device that receives an output signal (I_{M}) of the measurement amplifier circuit (217), to record the normal-operation currents and the fault currents,
wherein the measurement amplifier circuit (217) is a single-channel measurement amplifier circuit (217), comprising
a measurement amplifier (502) that reproduces an overall dynamic range of the voltage drop (Uᵢₙ) across the shunt resistor (203), and
a compression stage (503),
wherein the compression stage (503) receives an output signal of the measurement amplifier (502),
wherein the compression stage (503) has at least two different transfer functions (tf₄₀₁, tf₄₀₂),
wherein a first transfer function (tf₄₀₁) of the at least two different transfer functions (tf₄₀₁, tf₄₀₂) converts a measurement range of the normal-operation currents at high resolution, and
wherein a second transfer function (tf₄₀₂) of the at least two different transfer functions (tf₄₀₁, tf₄₀₂) compresses the dynamic range of the voltage drop across the shunt resistor (203) and converts a measurement range of the fault currents into the output signal (I_{M}) of the measurement amplifier circuit (217) at lower resolution than the first transfer function (tf₄₀₁).

12. The monitoring apparatus according to claim 11,
wherein the evaluation device is a protective device (211) for traction power applications.

13. The monitoring apparatus according to claim 11,
wherein the first transfer function (tf₄₀₁) and the second transfer function (tf₄₀₂) are each linear functions having different gradients (c₁, d₁).

14. The monitoring apparatus according to claim 13,
wherein the first transfer function (tf₄₀₁) has a first gradient (c₁) that corresponds to a multiple of at least 5 times a second gradient (d₁) of the second transfer function (tf₄₀₂).

15. The monitoring apparatus according to claim 11, wherein the first transfer function (tf₄₀₁) is designed so as to be shifted at an origin.

16. The monitoring apparatus according to claim 11,
wherein the first transfer function (tf₄₀₁) and the second transfer function (tf₄₀₂) are made up of two or more different sub-transfer functions.

17. The monitoring apparatus according to claim 11,
wherein the first transfer function (tf₄₀₁) and the second transfer function (tf₄₀₂) are designed to reproduce positive and negative currents.

18. The monitoring apparatus according to claim 11,
wherein the measurement amplifier circuit (217) is designed to have DC isolation between an input (500) and an output (510).

19. The monitoring apparatus according to claim 11,
wherein power is supplied to the measurement amplifier circuit (217) by way of a DC-isolating auxiliary power supply (208).

20. The monitoring apparatus according to claim 11,
wherein cable break monitoring for a cable connection (218) between the shunt resistor (203) and the measurement amplifier circuit (217) is accomplished by virtue of the measurement amplifier (502) being able to impress a low test current into the cable connection (218) and via the shunt resistor (203).
